(19) United States
(12) Patent Application Publication
(10) Pub. No.: US 2013/0176699 A1
(43) Pub. Date: Jul. 11, 2013

(54) METHOD AND APPARATUS FOR DEPOSITION

(71) Applicants: Dan Tonchev, Plovdiv (BG); Stoeva Zlatka, Cambridge (GB)

(72) Inventors: Dan Tonchev, Plovdiv (BG); Stoeva Zlatka, Cambridge (GB)

(73) Assignee: DZP TECHNOLOGIES LIMITED, Cambridge (GB)

(21) Appl. No.: 13/703,482

(22) PCT Filed: Jun. 10, 2011
(86) PCT No.: PCT/GB2011/051086

§ 371 Date: Feb. 28, 2013

(30) Foreign Application Priority Data
Jun. 11, 2010 (GB) 1009847.3

(51) Int. Cl. H05K 3/10

(52) U.S. Cl. CPC H05K 3/10
USPC 361/760; 427/596; 118/723 R; 174/250; 524/548; 524/555; 524/556; 524/591; 524/571; 524/428

(57) ABSTRACT

The present invention relates to a method of depositing a composition on a receiving substrate to form a printed object, the method comprising the steps of providing: (1) a receiving substrate; (2) a source of near-infra-red laser radiation which is a pulsed laser source or an array of pulsed lasers; (3) a support transparent to near-infra-red laser radiation, the support being positioned between the receiving substrate and the laser source; and a composition which is in contact with the transparent support and which is positioned between the transparent support and the receiving substrate, wherein the composition comprises: (a) a functional material in particulate form capable of absorbing near-infra-red laser radiation, (b) an oligomer and/or polymer, (c) water, and (d) optionally additives, the method comprising directing near-infra-red laser radiation through the transparent support and into the composition and thereby causing the composition to be transferred from the transparent support across a gap to the receiving substrate and causing oligomer and/or polymer to solidify on the receiving substrate, thus forming a printed object on the receiving substrate, wherein the printed object is electrically conductive.

The present invention further provides apparatus, devices, and compositions for use with the method described.

### FIELD OF THE INVENTION

The invention is related to a deposition method for the fabrication of a printed object on a flexible or rigid substrate using additive laser assisted non-contact material transfer. The invention is suitable for the printing-like deposition of high precision patterns of useful functionality, for example metallic patterns of high electronic conductivity.

### DESCRIPTION OF THE RELATED ART

The emerging fields of printed and plastic electronics require the development of new processes and materials which make it possible to fabricate functional prints on flexible substrates such as polymers, papers, textiles and metal foils. Typically, the desired functionality is high electronic conductivity although other functionalities may also be required. Examples include electronic conductivity of controlled levels, dielectric and opto-electronic properties, ionic conductivity, light absorbing properties. These functionalities are useful in the fabrication of different components such as metallic contacts, connectors and current collectors in electronic devices; electrodes in super-capacitors and electrochemical batteries; photo-sensitive layers in solar cells and photodiodes; conducting layers in solar cells and displays, etc.

In modern industry, different methods and techniques are being developed to produce printed and plastic electronics products. Most notable examples include inkjet printing, screen printing and, more recently, flexographic printing in which special inks containing functional material are used to deposit functional tracks. All of these technologies have certain drawbacks which limit their applications. Importantly, all of these methods use different fluid compositions which contains significant amount of organic solvents which have to be removed by drying after the pattern deposition. During drying, functional material from the ink diffuses and migrates to the printing substrate. This can be detrimental to the operation of the obtained printed device. For example, it is known that metal atoms from printed metal layers in diodes and transistors easily diffuse and migrate into the adjacent layers, leading to short-circuit and failure of the device. Additionally, the requirement to use specific solvents in those fluid compositions limit the number and scope of functional materials which can be deposited by traditional printing methods such as inkjet, flexography, screen printing etc.

Laser-assisted printing-like deposition represents a promising alternative to the existing, above-mentioned methods for fabricating printed electronics. In general, the laser printing-like deposition methods are digitalised, high-precision methods, with the additional flexibility of using laser systems of different wavelength and power to produce different printed products.

Laser direct write (LDW) techniques are known in the prior art. These techniques are widely used because they enable computer controlled 2D and 3D pattern formation, and are suitable for scaling up in industrial applications. LOW methods are very versatile because they allow to add, remove and modify many different types of materials without the need of a contact between the material and the printing tool (e.g. a nozzle). Additionally, the LDW methods allow for precise control of the material processing with high resolution and precision, often impossible to achieve by other methods such as screen printing, lithography or stamping. This and similar other laser deposition methods are mostly contact transfer methods for material addition and have been described in the prior art. An excellent review of the current state of art was presented by Arnold et al (2007). One of the most popular is the so-called laser-induced forward transfer (LIFT). In LIFT, part of the material evaporates (ablates) as it absorbs the laser radiation whereas the rest of the material is transferred to a substrate. LIFT makes use of powerful UV lasers which generate sufficient energy to vaporise part of the material.

In contrast to LIFT in which evaporation is the core process during the material transfer, the present invention describes a novel process and device that use specific laser energy and wavelength in the near-infra-red (NIR) range which is advantageously used to propel NIR-absorbing material from a media to a substrate, without decomposing or substantially changing its chemical composition. The deposited tracks obtained in this way show surprisingly improved functional properties, including high electronic conductivity and improved adhesion to the substrate.

Other relevant prior art related to laser transfer includes the following examples.

U.S. Pat. No. 6,805,918 B2 describes a laser transfer process where a portion of the transferred material is evaporated under the effect of the laser irradiation, whereas the non-evaporated portion of the transferred material is propelled by the evaporating fluid towards the receiving substrate. More specifically, the evaporating portion generates a high-pressure burst that propels the non-evaporating material at a defined location across a gap to a receiving substrate. The non-evaporated portion of the transferred material may comprise of almost any functional material in the form of powders, flakes or other particles that possesses an intrinsic property or properties integral to the proper functioning of any variation or combination of an active electronics, magnetic, optical, chemical, biological, actuating or metrological application. Because of the significant amount of fluids required in this application, and the need of subsequent drying, the obtained deposits are prone to inter-layer diffusion and migration which could lead to failure of the fabricated device.

U.S. Pat. No. 6,638,669 granted to Schneider et al describes the transfer of reactive polymer composition using laser light of wavelength 700 to 1600 nm. The composition also contains substances which convert the laser radiation into heat energy helping in this way to soften and transfer the said composition to the donor substrate. The object of this prior art is to provide a method for imaging a lithographic printing-plate cylinder for offset printing wherein the printing-plate cylinder offers a service life adequate for longest possible printing run with constant print quality. There is no intended use of the transferred material as electronic, optical or other functional material other than mechanically robust material which comprises a part of the printing-plate cylinder.

None of the aforementioned prior art which has intended use in the printing industry describes a method or a process capable of fabricating a printed object of specific electronic, electric, optical, magnetic or other similar physical properties which make such objects suitable for application in electrical or electronic devices, and especially in multi-layered electrical and electronics devices.

### SUMMARY OF THE INVENTION

The present invention provides a laser deposition method to produce one or more of electronically conducting, semiconductive, resistive, optical and other functional printed objects which are obtained directly in a relatively dry form after deposition on the substrate.

According to a first aspect of the invention, there is provided a method of depositing a composition on a receiving substrate to form a printed object, the method comprising providing:
a receiving substrate
a source of near-infra-red laser radiation which is a pulsed laser source or an array of pulsed lasers
a support transparent to near-infra-red laser radiation, the support being positioned between the receiving substrate and the laser source
a composition which is in contact with the transparent support and which is positioned between the transparent support and the receiving substrate,
wherein the composition comprises (a) a functional material in particulate form capable of absorbing near-infra-red laser radiation, (b) an oligomer and/or polymer, (c) water, and (d) optionally additives,
the method comprising directing near-infra-red laser radiation through the transparent support and into the composition and thereby causing at least a portion of the composition to be transferred from the transparent support across a gap to the receiving substrate and causing oligomer and/or polymer to solidify when deposited on the receiving substrate, thus forming a printed object on the receiving substrate, wherein the printed object is electrically conductive.

The substrate may be one which already includes a previously deposited layer of the composition of the present invention, or another electrically conductive material.

Preferably, there is a gap between the composition which is in contact with the transparent support and the receiving substrate. This gap is preferably precisely regulate. This gap distance may be modified to tune the properties of the deposited material.

Preferably, the functional particles comprise or consist of a near-infra-red absorbing material selected from the group consisting of metals, carbon materials, organic or inorganic semiconductors and conductive polymer powders. More specifically, examples include but are not limited to carbon (nano)tubes, carbon (nano)fibres, fullerenes, graphene, carbon black, carbon (nano)ribbons, metal particles comprising copper, nickel, platinum, palladium, silver, gold, aluminium, zinc; inorganic compounds such as transition metal oxides, nitrides and sulphides. Particularly preferred functional particles comprise silver, copper or carbon.

Further, the functional particles may comprise thermally stable organic semiconductors, such as phthalocyanines. These materials are suitable for the deposition of light-absorbing layers in photovoltaic cells.

The functional particles of the present invention are preferably highly loaded with near-infra-red absorbing material, preferably greater than 50% by weight of the particles is near-infra-red absorbing material, more preferably greater than 70% by weight near-infra-red absorbing material, preferably greater than 80% by weight near-infra-red absorbing material, preferably greater than 90% by weight near-infra-red absorbing material, preferably, less than 95% by weight. Such near-infra-red absorbing material is preferably metal and/or carbon. Such material possesses the necessary viscosity to form a film due to the presence of water. Preferably, where a carbon based material is used as the near-infra-red absorbing material, it is present in an amount of at least 35% by weight of the particles.

Preferably, the near-infra-red absorbing material is present in an amount of greater than 50% by weight of the entire composition, more preferably greater than 70% by weight of the entire composition, preferably greater than 80% by weight of the entire composition, preferably greater than 90% by weight of the entire composition, preferably, less than 95% by weight of the entire composition. Preferably, where a carbon based material is used as the near-infra-red absorbing material, it is present in an amount of at least 35% by weight of the entire composition.

The water is preferably present in up to 30% by weight, more preferably not more than 25% by weight, more preferably not more than 10% by weight of the entire composition, preferably greater than 2% by weight of the entire composition. Preferably the water is deionized.

Preferably, the water comprises 10% or less by weight of an alkaline material, more preferably 0.05% to 7.5% by weight of an alkaline material, more preferably 0.1-5% by weight of an alkaline material. Preferably, the alkaline material is selected from the group consisting of volatile materials. Preferably, the alkaline material is selected from volatile materials which have a boiling point of less than 80° C., more preferably less than 50° C., more preferably less than 25° C., more preferably less than 10° C. Preferably, the alkaline material is soluble in water. Preferably, the alkaline material is at least 25% soluble in water at 0° C. Preferably, the alkaline material is ammonia.

Preferably, the pH of the composition when on the support of the present invention is in the range of 7-13, more preferably 7-11, more preferably 7.5-10, more preferably 8-9.5. When the pH is in this range, the composition preferably contains an acrylic oligomer and/or polymer.

Preferably, the composition comprises at least 35% by weight of the functional particles, more preferably at least 50% by weight functional particles, more preferably at least 70% by weight functional particles, more preferably at least 75% by weight functional particles, preferably not more than 95% by weight functional particles, preferably not more than 85° /0 by weight functional particles.

Preferably, the composition comprises at least 50% by volume of the functional particles, more preferably at least 60% by volume functional particles, more preferably at least 70% by volume functional particles, more preferably at least 75% by volume functional particles, preferably not more than 95% by volume functional particles, preferably not more than 85% by volume functional particles.

The composition used in the invention may take the form of a solid, paste, gel or thixotropic liquid.

During deposition, preferably less than 10% by weight of the composition is thermally degraded, more preferably less than 5%, preferably less than 1%.

The receiving substrate is preferably selected from the group consisting of metal foil, paper, cardboard, textile and plastic. The receiving substrate is preferably fed using a feeding system similar to traditional printing press paper feeders.

Preferably, the gap (i.e., the distance between the NIR transparent media and the substrate) is below 2 mm, preferably in the range of 0.05 mm to 1 mm, more preferably 0.1 mm to 0.75 mm, most preferably, about 0.5 mm. This gap is important as it allows the resolution of the printing to be improved. The receiving substrate may be manipulated in different directions to achieve the desired pattern. Optionally, the laser deposition device can be attached to a commercial printing press and synchronized with the printing process as desired.

Preferably, the gap is an air gap, or it may comprise one or more inert gases, such as nitrogen or argon.

Preferably, the water is homogeneously mixed with the oligomer and/or polymer.

Preferably, the oligomer and/or polymer is used to bind the functional particles when deposited on the surface of the receiving substrate. Preferably, the oligomer and/or polymer is used to bind or adhere the functional particles to the surface of the receiving substrate.

Preferably the oligomer or polymer is a non-reactive oligomer or polymer, i.e., there are less than 5% by weight, more preferably less than 1% by weight of functional groups which are capable of reaction (e.g. cross-linking) during the method of the present invention. Preferably, there are no reactive functional groups present on the oligomer or polymer. Preferably, the polymer is selected from the group consisting of polyacetals, polyamides, polyimides, polyesters, polycarbonates, polyamide-imides, polyamide-esters, polyamide ethers, polycarbonate-esters, polyamide-ethers, polyacrylates, polyacrylics, elastomers such as polybutadiene, copolymers of butadiene with one or more other monomers, polyalkylmethacrylates, polyethylene, polypropylene, polystyrene, polyvinylacetate and polyvinylalcohol.

Preferably, the oligomer and/or polymer is selected from the group consisting of water-soluble non-crosslinking oligomers and polymers.

Preferably, the oligomer and/or polymer decreases its solubility in water when the pH decreases. In this embodiment, the oligomer and/or polymer is preferably an acrylic polymer.

Preferably, the oligomer and/or polymer is selected from the group consisting of water-soluble non-crosslinking oligomers and polymers selected from the group consisting of acrylics, vinyls, butadienes, styrenes, and polyurethanes.

Preferably, the composition comprises at least 5% by weight of a film forming polymer, more preferably, at least 10% by weight thereof.

Preferably, the oligomer and/or polymer used in the compositions of the present invention are not reactive or unstable in the presence of water.

The composition of the present invention preferably contains an oligomer and/or polymer of molecular weight of at least 100000, preferably at least 30000.

Preferably, the oligomer and/or polymer is present in the composition in an amount of up to 40% by weight of the entire composition, preferably between 5 and 25% by weight of the entire composition.

Preferably, the functional particles have an average particle size of up to about 500 μm, preferably from about 0.01 μm to about 200 μm, preferably from about 0.1 μm to about 100 μm, preferably from about 1 μm to about 50 μm.

Preferably, the composition immediately (within 5 seconds) of deposition on the substrate, has a water content of less than 5% by weight of the deposited composition, preferably less than 1% by weight, preferably less than 0.5% by weight of the composition.

Preferably, the composition has an organic solvent content of less than 5% by weight of the composition, preferably less than 1% by weight, preferably less than 0.5% by weight of the composition.

Preferably, the composition comprises a solvent which consists essentially of water.

Preferably, the weight percentage of functional particles in the printed object is from 0.9 to 1.1 times, preferably from 0.95 to 1.05 times, the weight percentage of functional particles in the composition (ink).

In a preferred embodiment, there is provided a method and device for pulsed laser deposition by film material transfer where an active material composition is transferred directly, and across a gap, from a media to a receiving substrate under the effect of normally near-infra-red (NIR) but also with some other (e.g. eximer pulsed laser irradiation) to form a printed object which shows functional properties suitable for application in electronic devices. These properties include one or more properties selected from the group consisting of high electronic conductivity, photo-conductivity, light absorption, photovoltaic effects, etc. The deposition process is significantly simplified compared with methods described in the prior art because it does not involve any intermediary coatings and layers, and does not involve significant evaporation and removal of reaction gases or solvents once deposition on the receiving substrate has taken place (only during propelling). The material being transferred arrives at the receiving substrate in a sufficiently dry form and there is no need for additional drying or curing. This prevents or reduces diffusion and migration of the transferred functional material to adjacent layers. A slightly melted part of the binding polymer serves as a conductive adhesive to ensure the necessary contact adhesion to the surface.

The presence of a gap, rather than intimate contact, between the media and the receiving substrate is particularly advantageous because it enables one to tune the transfer process in terms of transfer distance and beam optics, affecting in this way the resolution, size, shape, and morphology of the obtained printed object and to achieve adequate film drying during propulsion across the gap.

In a second aspect of the present invention, there is provided an apparatus for laser assisted material deposition comprising:
a pulsed near-infra-red laser source and a near-infra-red transparent support and
means for providing on the transparent support a layer of a composition according to the first aspect of the invention (including any combination of the recited preferred features) which is suitable for laser assisted deposition; and,
means for supplying further amounts of said composition to the same area of the transparent support to replenish the layer.

In a third aspect of the present invention, there is provided a:
(a) laser jet transfer device which is a combination of pulsed laser source with appropriate pulse energy and wavelength according to a particular use able to produce tuneable short pulse irradiation;
(b) a composition as defined in the first aspect of the invention (including any combination of the recited preferred features);
(e) a film forming device.

According to the third aspect of the invention, the tuneable short pulse irradiation may include Q-Switch. Modelock, etc., pulse tuning. The laser irradiation may be collimated by a collimator to a particular pattern size or spot. Preferably, it is able to transfer instantly film-like active material trough a gap without affecting the active materials' properties. The particulate functional material is preferably not affected by the short pulse irradiation during the propulsion.

According to a fourth aspect of the invention, there is provided a composition suitable for laser assisted deposition, comprising any of the composition features recited above in respect of the first aspect of the invention. Preferably, the composition comprises at least 60 wt % of functional particles capable of absorbing near-infra-red laser radiation, water, a non-crosslinking oligomer and/or polymer, and optional additives, and viscosity at least 1 poise at 25° C., preferably at least 10 poise at 25° C. Preferably, the viscosity is in the range of 10-500 poise at 25° C.

Preferably, deposited conductive films obtained according to the present invention have sheet resistance in the range 5 milliohms per square (Ω/sq) to 100 megaohms per square. Preferably, the sheet resistance is in the range of 5 milliohms per square and 100 ohms per square for metal containing films, most preferably silver containing films.

Preferably, the film forming device is capable of replenishing the layer on the opposite side of the near-infra-red transparent support.

The oligomer and/or polymer preferably include some film forming polymers, such as polyvinylpyrrolidone, acrylamides, acrylics, polyurethane, butadiene, copolymers thereof, and similar polymers. Preferably, the polyurethane is derived from hydroxyl-terminated polyethers, polyesters and polybutadienes. The acrylic polymer may be polymethylmethacrylate, polyethyl methacrylate or polyhydroxyethylmethacrylate. Preferably, the film forming device is a permanent film forming device, and is preferably a cartridge, movable table, doctor blade, and the like.

Surprisingly, it is found that the use of water as a diluent for the oligomer or polymer is particularly advantageous in the laser transfer process for several reasons:
Water has a high heat capacity and absorbs electro-magnetic radiation in the NIR region. Therefore water plays the role of a NIR absorber, in addition to being a diluent for the film forming polymer. This improves the efficiency of the laser transfer process.
Because of the above-mentioned properties, water absorbs the majority of the pulse laser energy during the propulsion stage, thereby protecting the particulate functional material from problems such as oxidation, evaporation or combustion. This could lead to migration and diffusion of the particulate functional material, once deposited on the receiving substrate. As previously explained, these processes lead to short-circuiting and failures of the fabricated electronic devices.
Water with additives such as ammonia allows control over the pH of the composition. This may be particularly important because, as explained below, solubility of the non-crosslinking polymers may be made to depend on pH.
Water is also a preferred solvent or diluent in terms of environmental sustainability, health and safety.

In an embodiment where an alkaline material (such as ammonia) is included in the water component of the composition of the present invention, it is preferably removed more rapidly than water during the transfer process, thus the pH of the water composition decreases rapidly. In these conditions, the oligomer and/or polymer becomes less soluble and it precipitates and solidifies when deposited on the receiving substrate, without the need for further drying.

The present invention is also significantly better than prior art etching or lithographic techniques as only the material to be used in the electronic device is transferred to the substrate, rather than the etching of the majority of material from the support as is required by the prior art techniques. These prior art techniques are subtractive and generate significant waste

In another aspect of the invention, a NIR absorbing composition comprising non-crosslinking polymer is provided. Whereas the prior art teaches the use of cross-linking polymers in laser transfer in order to ensure mechanical robustness of the obtained deposits, it is disclosed in the present invention that cross-linked polymers by virtue of their dielectric properties are less desirable for the fabrication of electrically conductive objects. In order to obtain highly conductive components, for example electrical connectors in solar cells or LED devices, non-crosslinking polymers are preferably used according to the teaching of the invention disclosed herein.

In yet another aspect, the disclosed invention provides a printed object which is deposited on the receiving substrate in a substantially dry (i.e., substantially free of solvents and water) and non-fluid form. The printed object can be a component of a multilayer structure. The said multilayer structure is particularly well suited for use in electrical, electronic, photonic and memory devices because of the absence of inter-layer diffusion and migration of functional material in the printed object. The printed object is obtainable by deposition on a receiving substrate of a composition as defined in the first aspect of the invention.

As used herein “electrically conductive” preferably means a material which has an electrical conductivity in the range of greater than 10 siemens per metre at 20° C., more preferably greater than 10³ siemens per metre at 20° C., more preferably greater than 10⁴ siemens per metre at 20° C., more preferably greater than 10⁵ siemens per metre at 20° C., more preferably greater than 10⁶ siemens per metre at 20° C.

As used herein, “solidify” means to become more solid or to become relatively more dry. Preferably, to “solidify” means to reduce the amount of solvent and/or water in the composition by at least 2% based on the total weight of the composition, more preferably by at least 5%, more preferably at least 10%.

As used herein, a water-soluble oligomer or polymer is one which is soluble in water in an amount of greater than 0.1 mg per ml at 25° C., preferably greater than 0.5 mg per ml at 25° C., preferably greater than 1 mg per ml at 25° C., preferably greater than 5 mg per ml at 25° C., preferably greater than 10 mg per ml at 25° C.

### PREFERRED EMBODIMENTS OF THE INVENTION

In the present invention, the laser source consists of a pulsed near-infra-red (NIR—range 800 to 2000 nm) laser or array of lasers. The power density may be optimised according to the beam optics, gap distance, and desired resolution of the printed object. The power density may also be chosen in such a way that the electromagnetic energy is absorbed by the water diluent but is not sufficient to vaporise, decompose or combust the other components of the composition. The power density may be greater than 10⁴ W/cm². The energy per pulse is preferably up to 5 J/cm^{2,} for example, in the range of 10 micro joules/cm² to 5 J/cm². Recently developed laser diodes can achieve shorter pulses in the picosecond and femtosecond range and this makes the transfer system faster and more effective. The exact choice of the beam delivery system may be optimised depending on the required working distances, the focus spot size and absorption properties of the material to be transferred.

The device preferably comprises NIR transparent media consisting of inorganic or organic glass transparent to wavelength 800-2000 nm. The media is designed for multiple use, i.e. it remains substantially unchanged over multiple deposition cycles and is repeatedly coated with absorbing material during the deposition process. The support is preferably rigid. Preferably, the support is glass, such as silica glass, borosilicate glass or quartz.

The compositions of the present invention may optionally comprise one or more additives such as plasticizers, lubricants, surfactants (including anionic, cationic, amphoteric, non-ionic, twitterionic surfactants or mixtures thereof), emulsifiers, pigments, rheological additives, antistatic agents and the like. Preferred plasticisers include glycerine, ethylene glycol, ammonia, etc.

Preferably, the composition of the present invention is spread as a coating on the support and is preferably of a thickness of up to 20 μm, preferably 0.1 to 10 μm, more preferably 0.2 to 6 μm. Preferably, the coating has an average thickness of 0.1 to 10 μm, more preferably 0.2 to 6 μm.

In one embodiment, shown in FIG. 1, laser source (1) is located underneath the NIR transparent media (2). The media is supported on top of moving rollers (3) and can be moved in X-Y-Z directions. The absorbing material is contained in the two cartridges (4) and is constantly spread on the NIR transparent media, forming a coating of absorbing material (5) of thickness 0.2-6 μm. The NIR transparent media is permanently covered with the absorbing material using a doctor-blade arrangement to ensure uniform thickness. During irradiation from the laser, a spot of the absorbing material is propelled and transferred from the NIR transparent media to the receiving substrate (6) forming a printed object (7).

In another embodiment, illustrated on FIG. 2, the laser or array of lasers (8) is located inside a glass drum (9). The NIR transparent media (10) is constantly coated on the outside surface by a drum system (11) preferably with anilox drum or other system. Doctor blade (12) can also be used for better control of the coating thickness. The absorbing material is propelled from the NIR transparent media and deposited on the receiving substrate (13).

### Description of the Deposition Method

During irradiation, the absorbing material absorbs NIR radiation and the received energy is sufficient to propel or “jet” the absorbing material from the laser irradiation transparent media to the receiving substrate. During the transfer, the non-crosslinking polymer in the absorbing material dries or solidifies as a result of the processes described previously in the text.

The absorbing material reaches the receiving substrate in a substantially dry form. The resulting printed object consists of the functional particles embedded in the solidified polymer which normally but not necessarily is comprised of a conjugated polymer to improve further the functional properties of the active materials.

At least a portion, and preferably all of the functional particles in the absorbing materials are materials which absorb intensively in the wavelength range of interest, 800-2000 nm. For instance they may absorb at least 40%, preferably at least 50%, more preferably at least 70% NIR. The functional particles may have fibre, flake, tube or spherical morphology. The 1- and 2-dimensional morphologies are particularly advantageous for achieving the required functional properties, e.g. high electronic conductivity. These morphologies produce highly interconnected and continuous networks which provide percolation paths for electronic conduction.

As already explained in the text, water is particularly useful as a diluent in the present invention. Water is preferably the only component which is partially or fully removed during the deposition process as a waste product, making the disclosed deposition method highly advantageous in terms of health and safety.

The terms “comprising” and “comprises” means “including” as well as “consisting” e.g. a composition “comprising” X may consist exclusively of X or may include something additional e.g. X+Y.

The word “substantially” does not exclude “completely” e.g. a composition which is “substantially free” from Y may be completely free from Y. Where necessary, the word “substantially” may be omitted from the definition of the invention.

“Optional” or “optionally” means that the subsequently described event of circumstances may or may not occur, and that the description includes instances where said event or circumstance occurs and instances in which it does not.

“May” means that the subsequently described event of circumstances may or may not occur, and that the description includes instances where said event or circumstance occurs and instances in which it does not.

All of the above preferred embodiments of the present invention may be combined. Thus, none of the embodiments which are presented separately should be considered to be exclusive or non-combinable with other embodiments of the invention.

### Examples of Printed Objects

There are many applications where the printed objects obtained by the laser deposition process described herein can be advantageously used. Typically, these are applications which require a continuous film or grids of functional material which show a degree of electronic conductivity. Some examples are listed below, however, those skilled in the art can apply this teaching to other applications which are not explicitly mentioned here.

### Layers, Patterns and Grids of High Electronic Conductivity

These components are ubiquitous in the emerging field of plastic and flexible electronics as well as in traditional manufacture, for example highly conductive grids and patterns in solar cells, displays and light emitting diodes (LEDs), contacts in field effect and thin film transistors. The printed object obtained by the deposition process disclosed here comprises interconnected metallic particles coated with a polymer. The polymer is normally conjugated and this further increases the conductivity of the printed object. The printed objects obtained according to the present invention are particularly well suited to such applications because of the absence of inter-layer diffusion and migration of metal atoms in adjacent functional layers.

### Carbon-Based Electrodes for Super-Capacitors and Stretchable Electronics

Carbon nano-tubes networks are known for their excellent properties as electrode material in super-capacitors. Using the deposition method disclosed here, it is possible to fabricate high-quality electrodes comprising carbon nano-tubes embedded in a conducting polymer.

Carbon nanotube networks can also be used as electrical conductors in stretchable electronics components. Such an application is described, for example, by Sekitani et al (2008)

### Electrodes in Lithium Ion Batteries

Electrode materials for lithium ion batteries are traditionally formed using an intercalation oxide, sulphide, nitride or other compound, and a binder (conducting polymer, carbon black). Such a composition increases the electronic conductivity of the electrode, its mechanical robustness and stability, and improves the overall performance of the battery. Using the deposition methods disclosed herein, it is possible to fabricate electrodes suitable for such applications. The printed object in this case comprises transition metal oxide, nitride or sulphide particles embedded in conducting polymer or carbon black matrix.

### Carbon-Based Sensing Layers in Sensor Devices

Carbon-polymer composites are often used as sensing layers in strain sensors and angular displacement sensors. The application is based on the change of the electrical properties of the carbon-polymer composite, such as resistance, capacitance, impedance and/or conductivity during deformation. The disclosed invention provides a convenient method to fabricate the sensing component directly on a flexible substrate. This can be combined with the deposition of electrical conductors to connect the sensing component with other components of the sensor device.

### Heating Elements

Certain carbon-based polymer composites are very useful for such applications because they have strong thermal coefficient of resistance and can be used as a “heater” to warm the pharma pad, car seats, clothes, etc. The disclosed invention provides an efficient and convenient way to deposit such carbon-polymer heating components, in addition to the ability to deposit electrical connectors in the same manufacturing process.

### Cited Literature

Craig B. Arnold, Pere Serra and Alberto Pique, Materials Research Society Bulletin, Vol. 32, Jan. 2007, 23-31.
T. Sekitani, Y. Noguchi, K. Hata, T. Fukushima, T. Aida, T. Someya, Science, 2008, Vol. 321, 1468-1472.
PCT/US02/14629, R. C. Y. Auyeung, A. Pique, H. D. Young, R. Modi, H.-D. Wu, D. B. Chrisey, J. M. Fitz-Gerald, B. R. Ringeisen, Laser forward transfer of rheologicla systems.
WO 90/12342, D. M. Foley, E. W. Bennett, S. C. Slifkin, A near-infra-red absorbing coating and method for using same in colour imaging and proofing.

### Figures

FIG. 1. Schematic presentation of horizontal laser printing device.

FIG. 2. Schematic presentation of a laser printing device which uses a laser source located inside a drum. A conductive film (formed from the composition of the present invention) is applied to the substrate via use of the device.

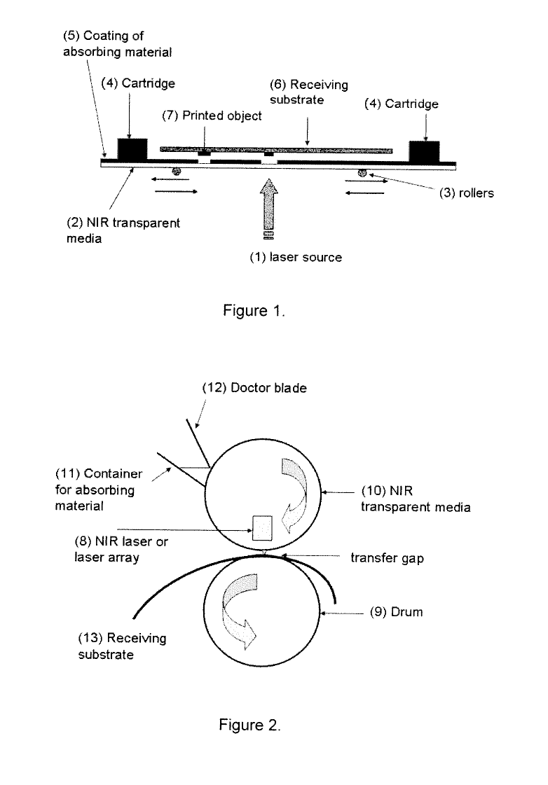

1-45. (canceled)

46. A method of depositing a composition on a receiving substrate to form a printed object, the method comprising providing:
a receiving substrate;
a source of near-infra-red laser radiation which is a pulsed laser source or an array of pulsed lasers;
a support transparent to near-infra-red laser radiation, the support being positioned between the receiving substrate and the laser source; and
a composition which is in contact with the transparent support and which is positioned between the transparent support and the receiving substrate,
wherein the composition comprises: (a) a functional material in particulate form capable of absorbing near-infra-red laser radiation, (b) an oligomer and/or polymer, (c) water, and (d) optionally additives,
the method comprising directing near-infra-red laser radiation through the transparent support and into the composition and thereby causing at least a portion of the composition to be transferred from the transparent support across a gap to the receiving substrate and causing the oligomer and/or polymer to solidify on the receiving substrate, thus forming a printed object on the receiving substrate, wherein the printed object is electrically conductive.

47. The method according to claim 46, wherein the functional particles of the near-infra-red absorbing material are selected from the group consisting of metals, carbon-based materials, organic or inorganic semiconductors, and conductive polymer powders.

48. The method according to claim 46, wherein the functional particles of the near-infra-red absorbing material contain greater than 35% by weight of near-infra-red absorbing material.

49. The method according to claim 46, wherein the distance between the near-infra-red transparent support and the substrate is in the range of either 0.05 mm to 2 mm or 0.1 mm to 0.5 mm.

50. The method according to claim 46, wherein the oligomer and/or polymer is present in the composition in an amount of up to 40% by weight of the entire composition.

51. The method according to claim 46, in which the receiving substrate is formed of flexible or stretchable material, or a previously deposited layer.

52. The method according to claim 46, wherein the receiving substrate is formed of rigid or flexible multi-layer material, preferably part of an assembled device such as an electrical or electronic device.

53. The method according to claim 46, in which the functional particles are in a form selected from the group consisting of tubes, nano-tubes, fibres, nano-fibres, wires, nano-wires, rods, nano-rods, ribbons, nano-ribbons, plates, nano-plates, flakes, and nano-flakes.

54. The method according claim 46, in which the oligomer and/or polymer is dried and/or solidified when reaching the receiving substrate.

55. The method according to claim 46, in which the oligomer and/or polymer form a thermoplastic structure in the composition.

56. The method according to claim 46, in which the printed object comprises a conducting non-cross-linked composition.

57. A method of making a product comprising a substrate and a pattern deposited thereon, wherein the pattern is deposited by the method according to claim 46.

58. A method of using a product made by the method of claim 57 as an electronic or electrical component.

59. A method of using a product according to claim 58 in which the component is: (1) a printed circuit board, (2) an electrode, (3) a sensing layer in a strain sensor or an angular displacement sensor, (4) a heating element, (5) a conductive contact layer in a solar cell, display, light-emitting diode, or transistor, (6) an electrode material for a super-capacitor and the functional material comprises carbonaceous material and the printed object comprises a conducting polymer, or (7) an electrode material for an electrochemical battery and the functional material comprises a transition metal oxide, nitride or sulphide particles, and the printed object comprises a conducting polymer or carbon black.

60. An apparatus for laser-assisted material deposition comprising:
a pulsed near-infra-red laser or an array of pulsed near-infra-red lasers as the laser source and a near-infra-red transparent support;
means for providing, on the transparent support, a layer of a composition as defined in claim 46; and
means for supplying further amounts of said composition to the same area of the transparent support to replenish the layer.

61. The apparatus according to claim 60 additionally comprising a receiving substrate.

62. The apparatus according to claim 60 in which the receiving substrate is an electronic or electrical component, including a multi-layered electronic or electrical component.

63. A printed object obtainable by the method according to claim 46.

64. A composition suitable for laser-assisted deposition comprising at least 60 wt % of functional particles capable of absorbing near-infra-red laser radiation, water, a non-cross linking oligomer and/or polymer, and optional additives, and a viscosity of at least 1 poise at 25° C., preferably at least 10 poise at 25° C.

65. A composition suitable for laser-assisted deposition comprising at least 60 wt % of functional particles capable of absorbing near-infra-red laser radiation, water, a non-cross linking oligomer and/or polymer, and optional additives, and a pH of greater than 7.

66. The composition according to claim 64 in which the functional particles are formed of materials selected from the group consisting of carbonaceous materials, metals, semiconductors, oxides, nitrides, sulphides, and thermally stable organic semiconductors.

67. The composition according to claim 64 in which the functional particles are in a form selected from the group consisting of tubes, nano-tubes, fibres, nano-fibres, wires, nano-wires, rods, nano-rods, ribbons, nano-ribbons, plates, nano-plates, flakes and nano-flakes.

68. The composition according to claim 65, wherein the water comprises up to 10% by weight of an alkaline material.

69. The composition according to claim 68, wherein the alkaline material is ammonia.

70. The composition according to claim 64, wherein the oligomer and/or polymer is present in the composition in an amount of up to 40% by weight of the entire composition.

71. The composition according to claim 64 in which the composition has a viscosity of not more than 20,000 poises at 25° C.
